(19) United States
(12) Patent Application Publication
(10) Pub. No.: US 2026/0329539 A1
(43) Pub. Date: Oct. 22, 2026

(54) ARITHMETIC COMPUTATION CIRCUITS WITH DECOMPOSED OPERAND PROCESSING

(71) Applicant: Koushik Krishnan, Saratoga, CA (US)

(72) Inventor: Koushik Krishnan, Saratoga, CA (US)

(21) Appl. No.: 19/639,362

(22) Filed: Apr. 6, 2026

Related U.S. Application Data
(60) Provisional application No. 63/791,110, filed on Apr. 18, 2025.
(60) Provisional application No. 63/819,003, filed on Jun. 6, 2025.

(51) Int. Cl. G06F 7/523; H03K 17/56

(52) U.S. Cl. CPC G06F 7/523; H03K 17/56

(57) ABSTRACT

Arithmetic computation circuits with decomposed operand processing are provided. A multiplier circuit comprises a current generation unit configured to generate a plurality of current signals, a plurality of switching units coupled to output nodes of the current generation unit, and a pulse generation unit configured to generate a plurality of pulse signals. Each switching unit comprises a first switch and a second switch in series. The first switch closes based on a respective digit value of a first or second digital operand. The second switch closes for a duration of a respective pulse signal. An integrator unit is coupled to outputs of the switching units. The closing of each switch causes a respective current signal to flow to the integrator unit for the duration, generating at least one output signal.

### CROSS-REFERENCE TO RELATED APPLICATIONS/INCORPORATION BY REFERENCE

This application claims priority to U.S. Provisional patent application Ser. No. 63/791,110 filed on Apr. 18, 2025, and U.S. Provisional patent application Ser. No. 63/819,003 filed on Jun. 6, 2025, the entire content of which is hereby incorporated herein by reference.

### TECHNICAL FIELD

The disclosure relates to arithmetic computation circuits and more particularly to technologies for performing multiplication and multiply-accumulate operations using mixed-signal processing techniques.

### BACKGROUND

Arithmetic computation circuits form the foundation of digital signal processing, machine learning accelerators, and various computing systems. These circuits perform operations such as multiplication and multiply-accumulate (MAC) operations that are fundamental to matrix-vector computations and neural network inference. As computational demands have increased, there has been growing interest in developing circuit architectures that can efficiently perform these operations while balancing considerations such as area, power consumption, and throughput.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In various embodiments of the disclosure, a multiplier circuit is described. The multiplier circuit includes a current generation unit configured to generate a plurality of current signals. The multiplier circuit further includes a plurality of switching units respectively coupled to a plurality of output nodes of the current generation unit. The multiplier circuit also includes a pulse generation unit configured to generate a plurality of pulse signals. Each switching unit of the plurality of switching units comprises a first switch and a second switch in series with the first switch. The first switch is configured to close based on a respective digit value of a set of digital values of a first digital operand or a second digital operand. The second switch is configured to close for a duration of a respective pulse signal of the plurality of pulse signals. The multiplier circuit additionally includes an integrator unit coupled to outputs of the plurality of switching units. The closing of each of the first switch and the second switch causes a respective current signal of the plurality of current signals to flow to the integrator unit for the duration. The integrator unit is configured to generate at least one output signal based on the flow of the respective current signal.

In various embodiments of the disclosure, a multiply-accumulate (MAC) circuit is described. The MAC circuit includes a plurality of multiplier circuits. Each multiplier circuit of the plurality of multiplier circuits comprises a current generation unit configured to generate a plurality of current signals and a plurality of switching units respectively coupled to a plurality of output nodes of the current generation unit. Each switching unit of the plurality of switching units comprises a first switch and a second switch in series with the first switch. The first switch is configured to close based on a respective digit value of a set of digital values of a respective first digital operand of a first operand vector or a respective second digital operand of a second operand vector. The second switch is configured to close for a duration of a respective pulse signal of a plurality of pulse signals. The MAC circuit further includes a pulse generation unit configured to generate the plurality of pulse signals. The MAC circuit also includes a plurality of shorted output nodes, wherein each shorted output node of the plurality of shorted output nodes is coupled to an output of a respective switching unit of each multiplier circuit of the plurality of multiplier circuits. The closing of each of the first switch and the second switch causes a respective current signal of the plurality of current signals to flow to a respective shorted output node of the plurality of shorted output nodes. The MAC circuit additionally includes an integrator unit coupled to the plurality of shorted output nodes, wherein the integrator unit is configured to accumulate charge based on the flow of the respective current signal from the respective switching unit of each multiplier circuit of the plurality of multiplier circuits to generate at least one output signal.

In various embodiments of the disclosure, a method is described. The method includes generating, by a current generation unit, a plurality of current signals. The method further includes generating, by a pulse generation unit, a plurality of pulse signals. The method also includes closing a first switch of each switching unit of a plurality of switching units based on a respective digit value of a set of digital values of a first digital operand or a second digital operand, wherein each switching unit of the plurality of switching units is coupled to a respective output node of a plurality of output nodes of the current generation unit, and wherein each switching unit of the plurality of switching units comprises the first switch and a second switch in series with the first switch. The method additionally includes closing the second switch of each switching unit of the plurality of switching units for a duration of a respective pulse signal of the plurality of pulse signals. The method further includes flowing, responsive to the closing of each of the first switch and the second switch, a respective current signal of the plurality of current signals to an integrator unit coupled to outputs of the plurality of switching units. The method also includes generating, by the integrator unit, at least one output signal based on the flow of the respective current signal.

The foregoing general description of the illustrative embodiments and the following detailed description thereof are merely exemplary aspects of the teachings of this disclosure and are not restrictive.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following FIGURES, wherein:

FIG. 1 is a block diagram that illustrates a multiplier circuit configured to perform multiplication operations using decomposed operand processing, in accordance with an embodiment of the disclosure;

FIG. 2 is a diagram that illustrates a current generation unit for a multiplier circuit, in accordance with an embodiment of the disclosure;

FIG. 3 is a diagram that illustrates a multiplier circuit with a memory unit and pulse generation circuit, in accordance with an embodiment of the disclosure;

FIG. 4 is a diagram that illustrates a multiplier circuit with unit pulse signals and multiple integrator circuits, in accordance with an embodiment of the disclosure;

FIG. 5 is a diagram that illustrates a multiplier circuit with unit current signals and pulse signals proportional to place values, in accordance with an embodiment of the disclosure;

FIG. 6 is a diagram that illustrates a multiplier circuit with unit current signals and unit pulse signals, in accordance with an embodiment of the disclosure;

FIG. 7 is a diagram that illustrates a multiply-accumulate circuit with a plurality of multiplier circuits, in accordance with an embodiment of the disclosure; and

FIG. 8 is a flowchart depicting a method for performing a multiplication operation using a multiplier circuit, in accordance with an embodiment of the disclosure.

### DETAILED DESCRIPTION

Arithmetic computation circuits form the computational foundation of digital signal processing systems and machine learning accelerators. Multiplication operations and multiply-accumulate (MAC) operations represent fundamental building blocks in these systems, where efficient implementation of these operations directly impacts overall system performance, power consumption, and area utilization. Conventional digital implementations of multiplication circuits may require significant hardware resources, particularly when processing high-precision operands, leading to increased power consumption and reduced computational throughput.

Analog and mixed-signal approaches to arithmetic computation have emerged as alternatives to purely digital implementations. These approaches may leverage current-mode processing and time-domain techniques to perform multiplication operations in the analog domain. In current-mode processing, operand values may be represented as current magnitudes, while in time-domain processing, operand values may be represented as pulse durations. The combination of current-mode and time-domain processing may enable multiplication through the integration of current over time, where the accumulated charge represents the product of the two operands.

The present disclosure describes an architecture for performing multiplication operations based on decomposing operands using digit values and place values. A number X having M digits may be represented mathematically as X=Σᵢ₌₀^{M-1}Xᵢ·Pᵢ, where Xᵢ represents the digit value at position i and Pᵢ represents the place value at position i. For binary representation, each digit value Xᵢ may be either 0 or 1, and each place value Pᵢ may be 2ⁱ. For example, the number 15 in binary representation may be expressed as 1111, where each digit value is 1 and the place values are 1, 2, 4, and 8 for positions 0, 1, 2, and 3 respectively. The reconstruction of the number 15 may be computed as 1·1+1·2+1 4+1·8=15.

The multiplication of two operands X and Y may be performed by applying the distributive property to the decomposed representations of the operands. When the first operand Y is represented as a current value and the second operand X is decomposed into digit values and place values, the multiplication may be expressed as X·Y=Y·

$$X \cdot Y = Y \cdot {\sum }_{i = 0}^{M - 1} {X}_{i} \cdot {P}_{i} = {\sum }_{i = 0}^{M - 1} Y \cdot {X}_{i} \cdot {P}_{i} .$$

Xᵢ·Pᵢ. Each term Y·Xᵢ·Pᵢ represents a partial product where the current Y flows for a duration corresponding to the place value Pᵢ when the digit value Xᵢ is 1. The summation of these partial products yields the complete multiplication result.

The architecture described herein may include a current generation unit configured to generate a plurality of current signals based on a first digital operand. The current generation unit may include a current digital-to-analog converter that converts the first digital operand to an output current signal, and a current replication unit that replicates the output current signal to generate multiple identical current signals. The current replication unit may employ a current mirror configuration where a first transistor configured as a diode receives the output current signal and generates a bias voltage, and a parallel array of transistors coupled to the first transistor mirrors the output current signal to respective output nodes. The current replication unit may also be referred to as a current mirror block (CMB) or GM cell.

The architecture may further include a plurality of switching units respectively coupled to output nodes of the current generation unit. Each switching unit may include a first switch and a second switch in series with the first switch. The first switch may be configured to close based on a respective digit value of a set of digital values of a second digital operand, and the second switch may be configured to close for a duration of a respective pulse signal generated by a pulse generation unit. The pulse signals may have durations corresponding to place values of the second digital operand. When both the first switch and the second switch are closed, the respective current signal flows through the switching unit to an integrator unit, which accumulates charge based on the flow of current signals. The two switches in series implement the mathematical expression Pᵢ·Xᵢ where the first switch (digit value switch) controls whether the bit is on (1) or off (0), and the second switch (place value switch) controls the duration corresponding to the place value.

The architecture may support multiple configurations that provide flexible trade-offs between area and computation time. In a first configuration, the current signals may have magnitudes corresponding to the full value of the first digital operand, and the pulse signals may have durations corresponding to the place values of the second digital operand. The outputs of the switching units may be shorted together at a common node coupled to the integrator unit, and the output signal may represent the complete multiplication result in a single cycle. This configuration corresponds to a case where both current and time domains are not bit-spliced, with full current source Y×I and full pulse X×T_{U}.

In a second configuration, referred to as a bit-spliced configuration, the current signals may have magnitudes corresponding to the full value of the first digital operand, and each pulse signal may correspond to a unit pulse signal having a uniform duration. The outputs of the switching units may be kept separate, with each output representing a partial result of the multiplication operation. The partial results may be converted to digital values by a plurality of analog-to-digital converters, and a digital reconstruction unit may combine the digital values through shifting operations to generate the complete multiplication result. This configuration corresponds to a case where time is spliced but current is common, with Y replicated and individual results coming out.

In a third configuration, the current signals may be unit current signals having uniform magnitudes, and the pulse signals may have durations corresponding to the value of the second digital operand. This configuration corresponds a case where current is spliced with unit current sources and full X applied to each, with the place value applied later on digitally. In a fourth configuration, both the current signals and the pulse signals may be unit signals, with place values applied digitally during reconstruction. This configuration corresponds to a case where both are spliced with unit current sources and unit pulse signals, with both place values applied digitally. The fourth configuration may further include a third switch in series with the first switch and the second switch, where the third switch is configured to close based on a respective digit value of the second digital operand.

The bit-spliced configurations may provide simplified hardware implementations. When unit pulse signals are used, the pulse generation circuitry may be simplified to generate a single pulse width rather than multiple pulse widths corresponding to different place values. The unit pulse may be synchronized with clock signals used for memory refresh operations and other system timing, which is a very trivial thing to create and can easily sync with memory refresh. The digital reconstruction may apply place values through shifting operations, which may be implemented efficiently in digital logic. This is more powerful because digital reconstruction is just requires shifting of place values from left or right.

The architecture may support single-cycle operation where the closing of each of the first switch and the second switch of each switching unit occurs within a single cycle such that the output signal is generated in the single cycle. Single-cycle operation may be achieved when the switching units operate in parallel, with each switching unit processing a respective digit position of the second digital operand simultaneously. The parallel operation may enable high throughput multiplication with reduced latency compared to sequential processing approaches. In the bit-spliced configuration employing a current mirror arrangement, wherein memory stores the digit values of the operand X and a unit pulse signal is applied to each switching unit while maintaining separate output paths prior to digital reconstruction, the architecture incurs two primary overheads: the digital reconstruction processing and the requirement for N analog-to-digital converters. However, this configuration enables the generation of the multiplication result within a single operational cycle.

The architecture may be extended to support MAC operations through a MAC circuit comprising a plurality of multiplier circuits. Each multiplier circuit may include a current generation unit and a plurality of switching units as described above. The outputs of corresponding switching units from each multiplier circuit may be shorted together at shorted output nodes, and an integrator unit coupled to the shorted output nodes may accumulate charge based on the flow of current signals from all multiplier circuits. The shorting of outputs does not result in loss of information for completing the multiplication before accumulation because the terms contain the multiplication of the digits and their respective locations, with place values handled implicitly by the digital reconstruction unit. Any number of multiplication blocks can be attached to the same wire highway for accumulation.

The architecture may further support matrix-vector multiplication operations where a row of a matrix is simultaneously multiplied with multiple columns to produce a row of results. The streaming operation may apply one row to the entire matrix to produce a row of results, and then apply the next row to produce another row of results. This streaming approach may enable efficient processing of matrix operations commonly used in machine learning applications. In some embodiments, both operands may be streaming inputs with the output also streaming, such that no values are held or stored during operation, providing unique system-level properties.

A memory unit may be coupled to the plurality of switching units and configured to store the set of digital values of the first digital operand or the second digital operand. The memory unit may provide the digit values to control the first switches of the switching units, enabling the operand values to be stored and reused across multiple operations. The architecture may differentiate between configurations where memory controls the current unit with external input applied to the switch block, and configurations where memory controls the time unit with external input applied to the current unit. The architecture also supports differential versions where complementary currents I and I-bar flow into respective locations with dependent switch control such that when one switch is on the complementary switch is off.

In various embodiments of the disclosure, a multiplier circuit is described. The multiplier circuit includes a current generation unit configured to generate a plurality of current signals. The multiplier circuit further includes a plurality of switching units respectively coupled to a plurality of output nodes of the current generation unit. The multiplier circuit further includes a pulse generation unit configured to generate a plurality of pulse signals. Each switching unit of the plurality of switching units comprises a first switch and a second switch in series with the first switch. The first switch is configured to close based on a respective digit value of a set of digital values of a first digital operand or a second digital operand. The second switch is configured to close for a duration of a respective pulse signal of the plurality of pulse signals. The multiplier circuit further includes an integrator unit coupled to outputs of the plurality of switching units. The closing of each of the first switch and the second switch causes a respective current signal of the plurality of current signals to flow to the integrator unit for the duration. The integrator unit is configured to generate at least one output signal based on the flow of the respective current signal.

In various embodiments of the disclosure, the current generation unit comprises a current digital-to-analog converter configured to generate an output current signal representative of the first digital operand. The current generation unit further comprises a current replication unit coupled to the digital-to-analog converter. The current replication unit is configured to replicate the output current signal to generate the plurality of current signals.

In various embodiments of the disclosure, the current replication unit comprises a first transistor configured as a diode. The first transistor is configured to receive the output current signal and generate a bias voltage. The current replication unit further comprises a parallel array of transistors coupled to the first transistor. Each transistor of the parallel array of transistors is configured to receive the bias voltage. Each transistor of the parallel array of transistors is further configured to mirror the output current signal to a respective output node of the plurality of output nodes.

In various embodiments of the disclosure, a magnitude of each current signal of the plurality of current signals corresponds to a value of the first digital operand.

In various embodiments of the disclosure, the first switch is configured to close based on the respective digit value of the set of digital values of the second digital operand. The duration of each pulse signal of the plurality of pulse signals corresponds to a place value of respective digit value of the set of digital values of the second digital operand. Outputs of the plurality of switching units are shorted together at a common node coupled to the integrator unit. The at least one output signal represents a result of a multiplication operation between the first digital operand and the second digital operand.

In various embodiments of the disclosure, the first switch is configured to close based on the respective digit value of the set of digital values of the second digital operand. Each pulse signal of the plurality of pulse signals corresponds to a unit pulse signal. The at least one output signal comprises a plurality of output signals. Each output signal of the plurality of output signals represents a partial result of a multiplication operation between the first digital operand and the second digital operand.

In various embodiments of the disclosure, each current signal of the plurality of current signals is a unit current signal.

In various embodiments of the disclosure, the first switch is configured to close based on the respective digit value of the set of digital values of the first digital operand.

In various embodiments of the disclosure, each pulse signal of the plurality of pulse signals has the duration that corresponds to a value of the second digital operand.

In various embodiments of the disclosure, each pulse signal of the plurality of pulse signals is a unit pulse signal.

In various embodiments of the disclosure, each switching unit of the plurality of switching units further comprises a third switch in series with the first switch and the second switch. The third switch is configured to close based on the respective digit value of the set of digital values of the second digital operand. The closing of each of the first switch, the second switch, and the third switch causes the respective current signal of the plurality of current signals to flow to the integrator unit.

In various embodiments of the disclosure, the at least one output signal comprises a plurality of output signals. Each output signal of the plurality of output signals represents a partial result of a multiplication operation between the first digital operand and the second digital operand.

In various embodiments of the disclosure, the integrator unit comprises a plurality of integrator circuits. Each integrator circuit of the plurality of integrator circuits is configured to accumulate charge based on the flow of the respective current signal via a respective switching unit of the plurality of switching units.

In various embodiments of the disclosure, each integrator circuit of the plurality of integrator circuits comprises a capacitor coupled between an output node of the respective switching unit and a ground node.

In various embodiments of the disclosure, the multiplier circuit further includes an analog-to-digital conversion unit comprising a plurality of analog-to-digital converters respectively coupled to the plurality of integrator circuits. Each analog-to-digital converter of the plurality of analog-to-digital converters is configured to convert a respective output signal of the plurality of output signals to a respective digital value of a plurality of digital values. The multiplier circuit further includes a digital reconstruction unit coupled to the plurality of analog-to-digital converters. The digital reconstruction unit is configured to receive the plurality of digital values from the plurality of analog-to-digital converters. The digital reconstruction unit is further configured to combine the plurality of digital values through shifting operations to generate a digital output representing a result of the multiplication operation between the first digital operand and the second digital operand.

In various embodiments of the disclosure, the multiplier circuit further includes a reset circuit coupled to each integrator circuit of the plurality of integrator circuits. The reset circuit is configured to reset each of the plurality of integrator circuits to an initial state prior to the multiplication operation.

In various embodiments of the disclosure, the multiplier circuit further includes a memory unit configured to store the set of digital values of the first digital operand or the second digital operand.

In various embodiments of the disclosure, the closing of each of the first switch and the second switch of each switching unit of the plurality of switching units occurs within a single cycle such that the at least one output signal is generated in the single cycle.

In various embodiments of the disclosure, a multiply-accumulate (MAC) circuit is described. The MAC circuit includes a plurality of multiplier circuits. Each multiplier circuit of the plurality of multiplier circuits comprises a current generation unit configured to generate a plurality of current signals. Each multiplier circuit of the plurality of multiplier circuits further comprises a plurality of switching units respectively coupled to a plurality of output nodes of the current generation unit. Each switching unit of the plurality of switching units comprises a first switch and a second switch in series with the first switch. The first switch is configured to close based on a respective digit value of a set of digital values of a respective first digital operand of a first operand vector or a respective second digital operand of a second operand vector. The second switch is configured to close for a duration of a respective pulse signal of a plurality of pulse signals. The MAC circuit further includes a pulse generation unit configured to generate the plurality of pulse signals. The MAC circuit further includes a plurality of shorted output nodes. Each shorted output node of the plurality of shorted output nodes is coupled to an output of a respective switching unit of each multiplier circuit of the plurality of multiplier circuits. The closing of each of the first switch and the second switch causes a respective current signal of the plurality of current signals to flow to a respective shorted output node of the plurality of shorted output nodes. The MAC circuit further includes an integrator unit coupled to the plurality of shorted output nodes. The integrator unit is configured to accumulate charge based on the flow of the respective current signal from the respective switching unit of each multiplier circuit of the plurality of multiplier circuits to generate at least one output signal.

In various embodiments of the disclosure, a method is described. The method includes generating, by a current generation unit, a plurality of current signals. The method further includes generating, by a pulse generation unit, a plurality of pulse signals. The method further includes closing a first switch of each switching unit of a plurality of switching units based on a respective digit value of a set of digital values of a first digital operand or a second digital operand. Each switching unit of the plurality of switching units is coupled to a respective output node of a plurality of output nodes of the current generation unit. Each switching unit of the plurality of switching units comprises the first switch and a second switch in series with the first switch. The method further includes closing the second switch of each switching unit of the plurality of switching units for a duration of a respective pulse signal of the plurality of pulse signals. The method further includes flowing, responsive to the closing of each of the first switch and the second switch, a respective current signal of the plurality of current signals to an integrator unit coupled to outputs of the plurality of switching units. The method further includes generating, by the integrator unit, at least one output signal based on the flow of the respective current signal.

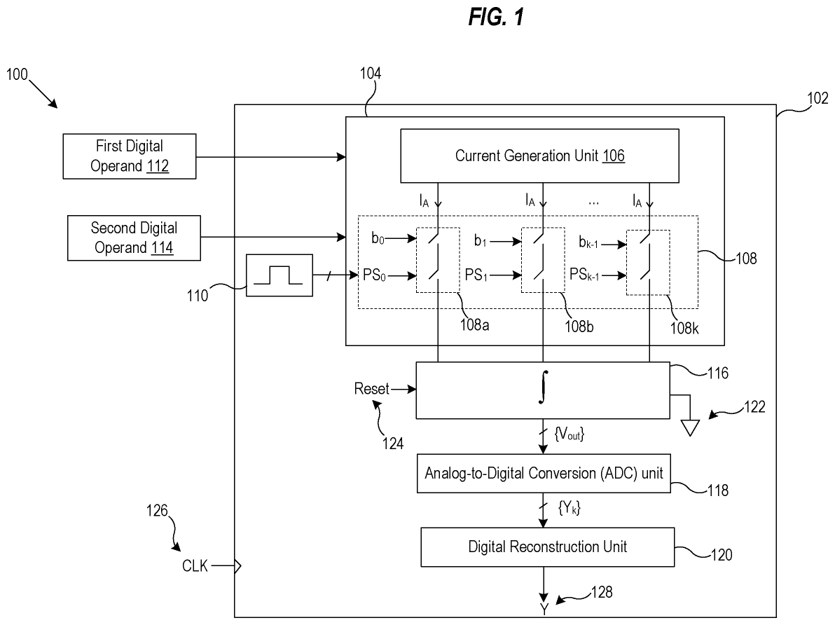

FIG. 1 is a block diagram 100 that illustrates a multiplier circuit 102 configured to perform multiplication operations using decomposed operand processing, in accordance with an embodiment of the disclosure. The multiplier circuit 102 includes a modulated current element 104, a current generation unit 106, a plurality of switching units 108, a pulse generation unit 110, an integrator unit 116, an analog-to-digital (ADC) conversion unit 118, and a digital reconstruction unit 120. The modulated current element 104 comprises the current generation unit 106, the plurality of switching units 108, and the pulse generation unit 110. The current generation unit 106 is configured to generate a plurality of current signals. The plurality of switching units 108 is respectively coupled to a plurality of output nodes of the current generation unit 106. The pulse generation unit 110 is configured to generate a plurality of pulse signals. The integrator unit 116 is coupled to outputs of the plurality of switching units 108 and is configured to generate at least one output signal based on the flow of a respective current signal of the plurality of current signals. The at least one output signal represents a result of a multiplication operation between a first digital operand 112 and a second digital operand 114. Alternatively, the at least one output signal comprises a plurality of output signals, where each output signal of the plurality of output signals represents a partial result of the multiplication operation between the first digital operand 112 and the second digital operand 114.

The current generation unit 106 is configured to receive the first digital operand 112 and generate the plurality of current signals. The current generation unit 106 includes the plurality of output nodes that provide the plurality of current signals to the plurality of switching units 108. Each current signal of the plurality of current signals is labeled as I_{A}, indicating that a magnitude of each current signal of the plurality of current signals corresponds to a value of the first digital operand 112. In certain embodiments, the current generation unit 106 comprises a current digital-to-analog converter configured to generate an output current signal representative of the first digital operand 112, and a current replication unit coupled to the current digital-to-analog converter. The current replication unit is configured to replicate the output current signal to generate the plurality of current signals. The current digital-to-analog converter includes a plurality of binary-weighted current sources that generate currents with magnitudes following a binary weighting scheme, such as Iₒ, 2Iₒ, 4Iₒ, and 2^{(k-1)}Iₒ, and a plurality of internal switches respectively coupled to the plurality of binary-weighted current sources. The plurality of internal switches are controlled by digits (e.g., bits) of the first digital operand 112 to selectively combine the binary-weighted currents and produce the output current signal I_{A}. The current replication unit comprises a first transistor configured as a diode, where the first transistor is configured to receive the output current signal and generate a bias voltage V_{B}, and a parallel array of transistors coupled to the first transistor. Each transistor of the parallel array of transistors is configured to receive the bias voltage V_{B} and mirror the output current signal to a respective output node of the plurality of output nodes. The current replication unit may also be referred to as a current mirror block (CMB) or GM cell. In some embodiments, each current signal of the plurality of current signals is a unit current signal Iᵤ having a uniform magnitude rather than a current signal proportional to the full value of the first digital operand 112.

With continued reference to FIG. 1, the plurality of switching units 108 includes a first switching unit 108a, a second switching unit 108b, and a kth switching unit 108k. Each switching unit of the plurality of switching units 108 is respectively coupled to a respective output node of the plurality of output nodes of the current generation unit 106. Each switching unit of the plurality of switching units 108 comprises a first switch and a second switch in series with the first switch. The first switch is configured to close based on a respective digit value of a set of digital values of the first digital operand 112 or the second digital operand 114. The second switch is configured to close for a duration of a respective pulse signal of the plurality of pulse signals. The first switching unit 108a receives a digit value b₀ and a pulse signal PS₀, the second switching unit 108b receives a digit value bᵢ and a pulse signal PS₁, and the kth switching unit 108k receives a digit value bₖ₋₁ and a pulse signal PSₖ₋₁. The digit values b₀, b₁, and bₖ₋₁ represent the respective digit values of the set of digital values of the second digital operand 114, while the pulse signals PS₀, PS₁, and PSₖ₋₁ are part of the plurality of pulse signals generated by the pulse generation unit 110. The closing of each of the first switch and the second switch causes a respective current signal of the plurality of current signals to flow to the integrator unit 116 for the duration of the respective pulse signal. In some embodiments, each switching unit of the plurality of switching units 108 further comprises a third switch in series with the first switch and the second switch. The third switch is configured to close based on a respective digit value of the set of digital values of the second digital operand 114. The closing of each of the first switch, the second switch, and the third switch causes the respective current signal of the plurality of current signals to flow to the integrator unit 116. The two switches in series implement the mathematical expression Pᵢ·Xᵢ, where the first switch (digit value switch) controls whether the bit is on (1) or off (0), and the second switch (place value switch) controls the duration corresponding to the place value.

The pulse generation unit 110 is configured to receive the second digital operand 114 and generate the plurality of pulse signals. The pulse generation unit 110 provides the plurality of pulse signals to the respective switching units of the plurality of switching units 108. In some embodiments, the duration of each pulse signal of the plurality of pulse signals corresponds to a place value of a respective digit value of the set of digital values of the second digital operand 114. For example, the plurality of pulse signals may have durations of 1, 2, 4, 8, and so on pulse widths representing place values in binary representation, where the first pulse signal is always 1 pulse, the second pulse signal is two times bigger, the third pulse signal is four times bigger, and so on. These are predetermined or standard pulses that are generated regardless of whether the corresponding digit value Xᵢ is 0 or 1. In some embodiments, each pulse signal of the plurality of pulse signals corresponds to a unit pulse signal having a uniform duration, which simplifies the pulse generation unit 110 to generate a single pulse width rather than multiple pulse widths corresponding to different place values. The unit pulse signal may be synchronized with clock signals used for memory refresh operations and other system timing. The pulse generation unit 110 may be synchronized with a clock signal 126 for generating the plurality of pulse signals with precise timing. In some embodiments, the pulse generation unit 110 comprises common hardware that generates pulses of integer numbers (1, 2, 4, etc.) that are shared across the plurality of switching units 108, with switches connected to memory that allow or block these pulses based on stored bit values.

As shown in FIG. 1, the closing of each of the first switch and the second switch causes the respective current signal of the plurality of current signals to flow to the integrator unit 116 for the duration of the respective pulse signal. The integrator unit 116 is coupled to outputs of the plurality of switching units 108 and is configured to generate the at least one output signal based on the flow of the respective current signal. In some embodiments, the at least one output signal comprises a plurality of output signals, and each output signal of the plurality of output signals represents a partial result of a multiplication operation between the first digital operand 112 and the second digital operand 114. In some embodiments, the integrator unit 116 comprises a plurality of integrator circuits, and each integrator circuit of the plurality of integrator circuits is configured to accumulate charge based on the flow of the respective current signal via a respective switching unit of the plurality of switching units 108. Each integrator circuit of the plurality of integrator circuits comprises a capacitor coupled between an output node of the respective switching unit and a ground node 122. The multiplier circuit 102 further comprises a reset circuit coupled to each integrator circuit of the plurality of integrator circuits, where the reset circuit is configured to reset each of the plurality of integrator circuits to an initial state prior to the multiplication operation. The integrator unit 116 is coupled to the ground node 122 and receives a reset signal 124 for resetting the integrator unit 116 to the initial state between operations. In some embodiments, the closing of each of the first switch and the second switch of each switching unit of the plurality of switching units 108 occurs within a single cycle such that the at least one output signal is generated in the single cycle. Single-cycle operation is achieved when the plurality of switching units 108 operate in parallel, with each switching unit processing a respective digit position of the second digital operand 114 simultaneously, enabling high throughput multiplication with reduced latency compared to sequential processing approaches. In some embodiments, outputs of the plurality of switching units 108 are shorted together at a common node coupled to the integrator unit 116, and the at least one output signal represents a complete result of the multiplication operation in the single cycle.

The integrator unit 116 provides a set of voltage outputs Vₒᵤₜ to the analog-to-digital (ADC) conversion unit 118. The ADC conversion unit 118 comprises a plurality of analog-to-digital converters respectively coupled to the plurality of integrator circuits of the integrator unit 116. Each analog-to-digital converter of the plurality of analog-to-digital converters is configured to convert a respective output signal of the plurality of output signals to a respective digital value of a plurality of digital values Yₖ. The ADC conversion unit 118 receives the clock signal 126 for synchronizing the conversion operations. In the bit-spliced version of the architecture, more analog-to-digital converters are needed on the output side, with N analog-to-digital converters required for an N-bit number. However, this trade-off enables simplified pulse generation circuitry and single-cycle operation.

With continued reference to FIG. 1, the digital reconstruction unit 120 is coupled to the plurality of analog-to-digital converters of the ADC conversion unit 118. The digital reconstruction unit 120 is configured to receive the plurality of digital values Yₖ from the plurality of analog-to-digital converters and combine the plurality of digital values through shifting operations to generate a digital output 128 representing a result of the multiplication operation between the first digital operand 112 and the second digital operand 114. The digital reconstruction unit 120 implements the shifting operations using digital accumulators where results arriving in sequence are shifted and accumulated according to their bit positions, with multiple accumulators handling overflow. The shifting operations apply place values to the partial results, where for binary representation with place values 2ⁱ, the digital reconstruction unit 120 shifts each partial result by the corresponding number of bit positions before accumulation.

The multiplier circuit 102 further comprises a memory unit coupled to the plurality of switching units 108 and configured to store the set of digital values of the first digital operand 112 or the second digital operand 114. In some embodiments, the memory unit controls the time unit and the external input is applied to the current generation unit 106, which differentiates this architecture from configurations where memory controls the current unit and external input is applied to the switch block. The architecture supports multiple configurations based on whether current and time domains are bit-spliced, such as a configuration where both are not bit-spliced with full current source Y×I and full pulse X×T_{U}; a configuration where time is spliced but current is common; a configuration where current is spliced with unit current sources and full X applied to each; and a configuration where both are spliced with unit current sources and unit pulse signals, with both place values applied digitally.

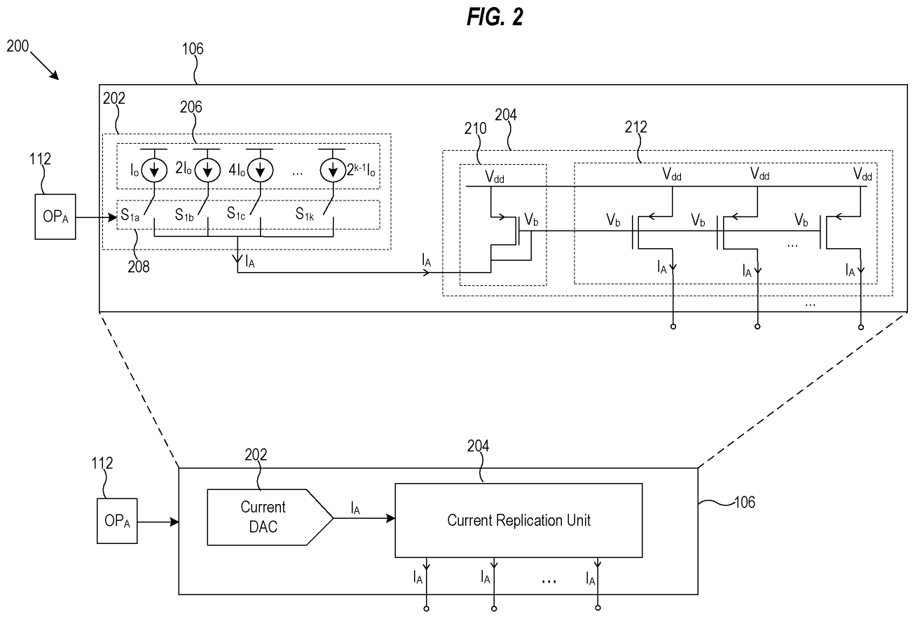

FIG. 2 is a diagram 200 illustrating a current generation unit 106 for a multiplier circuit, in accordance with an embodiment of the disclosure. FIG. 2 is explained in conjunction with elements from FIG. 1. With reference to FIG. 2, the diagram 200 shows the internal architecture of the current generation unit 106, which is configured to receive the first digital operand 112 as an input and generate a plurality of current signals. The current generation unit 106 comprises a current digital-to-analog converter 202 and a current replication unit 204 coupled to the current digital-to-analog converter 202. The current digital-to-analog converter 202 is configured to receive the first digital operand 112 and generate an output current signal I_{A} representative of the first digital operand 112. The current replication unit 204 is configured to replicate the output current signal I_{A} to generate the plurality of current signals, wherein a magnitude of each current signal of the plurality of current signals corresponds to a value of the first digital operand 112.

With continued reference to FIG. 2, the current digital-to-analog converter 202 includes a plurality of binary-weighted current sources 206 that generate currents with magnitudes following a binary weighting scheme. The plurality of binary-weighted current sources 206 generate currents shown as Iₒ, 2Iₒ, 4Iₒ, and 2^{(k-1)}Iₒ, where each current source of the plurality of binary-weighted current sources 206 generates a current proportional to a respective power of two. The current digital-to-analog converter 202 further includes a plurality of internal switches 208, labeled as S₁ₐ, S_{1b}, S_{1c}, and S₁ₖ, which are respectively coupled to the plurality of binary-weighted current sources 206. The plurality of internal switches 208 are controlled by the first digital operand 112 (as OP_{A}) to selectively combine the binary-weighted currents and produce the output current signal I_{A}. When a bit of the first digital operand 112 is set to 1, the corresponding internal switch of the plurality of internal switches 208 closes to include the respective binary-weighted current in the output current signal I_{A}. When a bit of the first digital operand 112 is set to 0, the corresponding internal switch remains open and the respective binary-weighted current is excluded from the output current signal I_{A}. In this manner, the current digital-to-analog converter 202 converts the first digital operand 112 from a digital value to a current I_{A} having a magnitude proportional to the value of the first digital operand 112. In some embodiments, the current digital-to-analog converter 202 may employ other configurations of current sources, such as unit current sources where multiple identical current sources are selectively combined using switches, or a resistive digital-to-analog converter (R-2R ladder or resistor string configuration) that generates the output current signal I_{A} through voltage-to-current conversion.

As further shown in FIG. 2, the current replication unit 204 comprises a first transistor 210 configured as a diode. The first transistor 210 is configured to receive the output current signal I_{A} from the current digital-to-analog converter 202 and generate a bias voltage V_{B}. The first transistor 210 is connected between a supply voltage V_{dd} and a node that establishes the bias voltage V_{B}. The current replication unit 204 further comprises a parallel array of transistors 212 coupled to the first transistor 210. Each transistor of the parallel array of transistors 212 is connected to the supply voltage V_{dd} and receives the bias voltage V_{B} at a gate terminal of the transistor. Each transistor of the parallel array of transistors 212 is configured to receive the bias voltage V_{B} and mirror the output current signal I_{A} to a respective output node of the plurality of output nodes. The parallel array of transistors 212 produces multiple identical current outputs I_{A} that flow to respective switching units of the plurality of switching units 108 of the multiplier circuit 102. The current replication unit 204 may also be referred to as a current mirror block (CMB) or GM cell. The current mirror configuration enables the output current signal I_{A} to be replicated for however many instances are needed, such that each replicated current signal has the same magnitude as the output current signal I_{A}.

The lower portion of the diagram 200 shows a simplified block representation of the same architecture. In the simplified block representation, the current digital-to-analog converter 202 receives the first digital operand 112 (as OP_{A}) and outputs the output current signal I_{A} to the current replication unit 204. The current replication unit 204 then generates the plurality of current signals as multiple replicated current outputs I_{A} for distribution to the plurality of switching units 108 via the plurality of output nodes of the current generation unit 106. The bias voltage V_{B} generated by the first transistor 210 is shared across the parallel array of transistors 212 to produce the replicated current outputs. This architecture differs from approaches where unit reference currents are combined using switches to generate a final current value, as the current digital-to-analog converter 202 generates the output current signal I_{A} first and then the current replication unit 204 replicates the output current signal I_{A} to the plurality of output nodes.

In some embodiments, the current generation unit 106 may comprise multiple replicated digital-to-analog converters instead of a single current digital-to-analog converter 202 with the current replication unit 204. In such embodiments, each digital-to-analog converter receives the same input from the first digital operand 112 and generates identical current outputs. The multiple replicated digital-to-analog converters may provide an alternative approach to generating the plurality of current signals without requiring a current mirror configuration, while still ensuring that a magnitude of each current signal of the plurality of current signals corresponds to the value of the first digital operand 112.

In some embodiments, the current replication unit 204 may be positioned outside a computing memory block, with the plurality of switching units 108 and a memory unit residing within a dense computing memory area. Positioning the current replication unit 204 outside the computing memory block may minimize area consumption within the dense computing memory area, where the plurality of switching units 108 and the memory unit are located. The current replication unit 204 generates the plurality of current signals that are distributed to the plurality of switching units 108 within the computing memory block, where each switching unit of the plurality of switching units 108 is respectively coupled to a respective output node of the plurality of output nodes of the current generation unit 106.

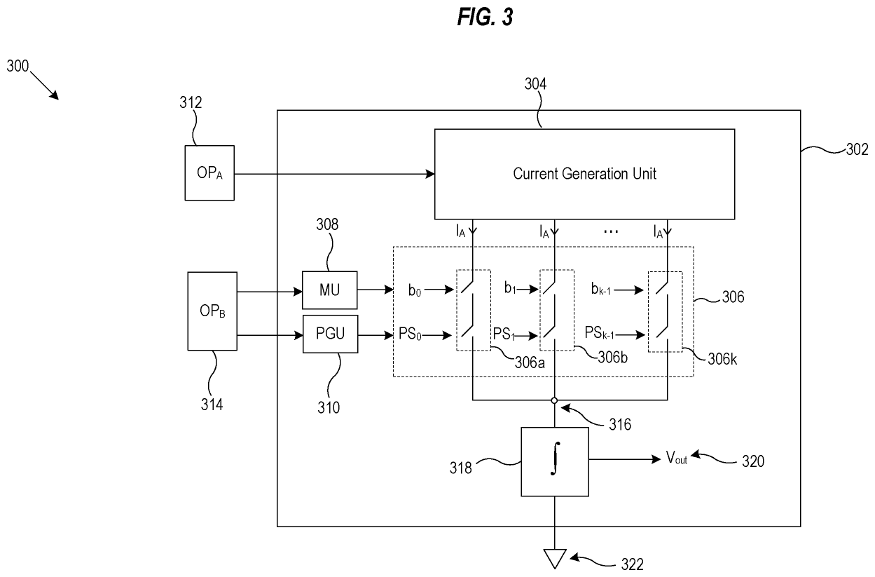

FIG. 3 is a diagram 300 illustrating a multiplier circuit 302 with a memory unit 308 and a pulse generation unit 310, in accordance with an embodiment of the disclosure. FIG. 3 is explained in conjunction with elements from FIG. 1 and FIG. 2. With reference to FIG. 3, the multiplier circuit 302 includes a current generation unit 304 configured to generate a plurality of current signals, a plurality of switching units 306 respectively coupled to a plurality of output nodes of the current generation unit 304, the memory unit 308 configured to store a set of digital values, the pulse generation unit 310 configured to generate a plurality of pulse signals, and an integrator unit 318 coupled to outputs of the plurality of switching units 306. The multiplier circuit 302 is configured to perform multiplication operations between a first digital operand 312 and a second digital operand 314, wherein the integrator unit 318 is configured to generate at least one output signal based on the flow of a respective current signal of the plurality of current signals.

The current generation unit 304 is configured to receive the first digital operand 312 (OP_{A}) and generate the plurality of current signals I_{A}. The current generation unit 304 includes the plurality of output nodes, each output node providing a respective current signal of the plurality of current signals. The magnitude of each current signal of the plurality of current signals corresponds to a value of the first digital operand 312. In some embodiments, the current generation unit 304 comprises a current digital-to-analog converter configured to generate an output current signal representative of the first digital operand 312, and a current replication unit coupled to the current digital-to-analog converter. The current replication unit is configured to replicate the output current signal to generate the plurality of current signals I_{A}, as described with reference to FIG. 2. The current replication unit comprises a first transistor configured as a diode. The first transistor is configured to receive the output current signal and generate a bias voltage, and a parallel array of transistors coupled to the first transistor. Each transistor of the parallel array of transistors is configured to receive the bias voltage and mirror the output current signal to a respective output node of the plurality of output nodes.

With continued reference to FIG. 3, the plurality of switching units 306 includes a first switching unit 306a, a second switching unit 306b, and a kth switching unit 306k. Each switching unit of the plurality of switching units 306 is respectively coupled to a respective output node of the plurality of output nodes of the current generation unit 304. Each switching unit of the plurality of switching units 306 comprises a first switch and a second switch in series with the first switch. The first switch is configured to close based on a respective digit value of the set of digital values of the second digital operand 314 (OPs). The second switch is configured to close for a duration of a respective pulse signal of the plurality of pulse signals. The first switching unit 306a receives a digit value b₀ and a pulse signal PS₀, the second switching unit 306b receives a digit value b₁ and a pulse signal PS₁, and the kth switching unit 306k receives a digit value bₖ₋₁ and a pulse signal PSₖ₋₁. The closing of each of the first switch and the second switch causes a respective current signal of the plurality of current signals to flow to the integrator unit 318 for the duration of the respective pulse signal.

The memory unit 308 (MU) is coupled to the plurality of switching units 306 and is configured to store the set of digital values of the first digital operand 312 or the second digital operand 314. In the embodiment of FIG. 3, the memory unit 308 stores the set of digital values of the second digital operand 314 and provides the respective digit values b₀, b₁, and bₖ₋₁ to control first switches of the first switching unit 306a, the second switching unit 306b, and the kth switching unit 306k, respectively. The digit values stored in the memory unit 308 control whether the first switches are closed (when the digit value is 1) or open (when the digit value is 0), enabling the operand values to be stored and reused across multiple operations. In this configuration, the memory unit 308 controls the time unit (the plurality of switching units 306) and the external input (the first digital operand 312) is applied to the current generation unit 304.

As further shown in FIG. 3, the pulse generation unit 310 (PGU) is configured to generate the plurality of pulse signals PS₀, PS₁, and PSₖ₋₁. The duration of each pulse signal of the plurality of pulse signals corresponds to a place value of a respective digit value of the set of digital values of the second digital operand 314. For example, the pulse signal PS₀ has a duration of 1 time unit corresponding to the place value 2⁰, the pulse signal PS₁ has a duration of 2 time units corresponding to the place value 2¹, and the pulse signal PSₖ₋₁ has a duration of 2^{k-1} time units corresponding to the place value 2^{k-1}. The plurality of pulse signals are predetermined or standard pulses that are generated regardless of whether the corresponding digit value is 0 or 1, with the first pulse signal always being 1 pulse, the second pulse signal being two times bigger, the third pulse signal being four times bigger, and so on. The pulse generation unit 310 comprises common hardware that generates pulses of integer numbers (1, 2, 4, etc.) that are shared across the plurality of switching units 306, with the first switches connected to the memory unit 308 that allow or block these pulses based on stored bit values. The pulse generation unit 310 may be synchronized with a clock signal and may generate pulses synchronized with memory refresh cycles of the memory unit 308, allowing the pulse timing to be coordinated with memory update. In some embodiments, the pulse generation unit 310 may be positioned outside a computing memory block as common hardware shared across the plurality of switching units 306, with the memory-controlled switches of the plurality of switching units 306 residing within a memory area.

With continued reference to FIG. 3, outputs of the plurality of switching units 306 are shorted together at a common node 316 coupled to the integrator unit 318. The closing of each of the first switch and the second switch of each switching unit of the plurality of switching units 306 causes a respective current signal I_{A} of the plurality of current signals to flow through the common node 316 to the integrator unit 318 for the duration of the respective pulse signal. The integrator unit 318 is configured to accumulate charge based on the flow of the plurality of current signals from the plurality of switching units 306 and generate an output signal 320 (Vₒᵤₜ) based on the accumulated charge. The integrator unit 318 is coupled to a ground node 322. The output signal 320 represents a result of a multiplication operation between the first digital operand 312 and the second digital operand 314. The shorting of outputs at the common node 316 does not result in loss of information for completing the multiplication because the terms contain the multiplication of the digits and their respective locations, with place values handled implicitly by the pulse signal durations.

In operation, the multiplier circuit 302 performs the multiplication operation by generating the plurality of current signals I_{A} having magnitudes corresponding to the value of the first digital operand 312 via the current generation unit 304. The magnitude of each current signal of the plurality of current signals corresponds to the value of the first digital operand 312. The memory unit 308 stores the set of digital values of the second digital operand 314, which control the first switches of the plurality of switching units 306. The pulse generation unit 310 generates the plurality of pulse signals with durations corresponding to the place values of the second digital operand 314, which control the second switches of the plurality of switching units 306. In this configuration, the first switch is configured to close based on the respective digit value of the set of digital values of the second digital operand 314, the duration of each pulse signal of the plurality of pulse signals corresponds to a place value of the respective digit value of the set of digital values of the second digital operand 314, outputs of the plurality of switching units 306 are shorted together at the common node 316 coupled to the integrator unit 318, and the output signal 320 represents a result of a multiplication operation between the first digital operand 312 and the second digital operand 314. The two switches in series implement the mathematical expression Pᵢ·Xᵢ, where the first switch (digit value switch) controls whether the bit is on (1) or off (0), and the second switch (place value switch) controls the duration corresponding to the place value. The closing of each of the first switch and the second switch of each switching unit of the plurality of switching units 306 occurs within a single cycle such that the output signal 320 is generated in the single cycle. The resulting current flow through the plurality of switching units 306 is accumulated by the integrator unit 318 at the common node 316 to produce the output signal 320 representing the complete multiplication result. The shorting of outputs at the common node 316 enables the partial products from each switching unit to be combined in the analog domain, producing the multiplication result in a single integration operation.

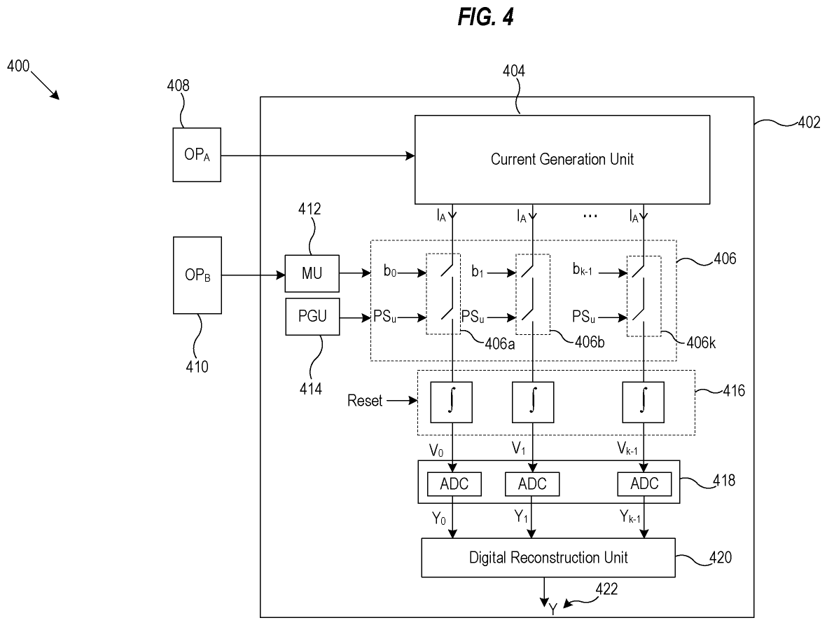

FIG. 4 is a diagram 400 illustrating a multiplier circuit 402 with unit pulse signals and multiple integrator circuits, in accordance with an embodiment of the disclosure. FIG. 4 is explained in conjunction with elements from FIG. 1, FIG. 2, and FIG. 3. With reference to FIG. 4, the multiplier circuit 402 includes a current generation unit 404 configured to generate a plurality of current signals, a plurality of switching units 406 respectively coupled to a plurality of output nodes of the current generation unit 404, a memory unit 412 configured to store a set of digital values, a pulse generation unit 414 configured to generate a plurality of pulse signals, an integrator unit 416 coupled to outputs of the plurality of switching units 406, an analog-to-digital conversion unit 418 comprising a plurality of analog-to-digital converters respectively coupled to the integrator unit 416, a digital reconstruction unit 420 coupled to the plurality of analog-to-digital converters, and a digital output 422. The multiplier circuit 402 is configured to perform multiplication operations between a first digital operand 408 and a second digital operand 410, wherein the integrator unit 416 is configured to generate at least one output signal based on the flow of a respective current signal of the plurality of current signals.

The current generation unit 404 is configured to receive the first digital operand 408 (OP_{A}) and generate the plurality of current signals I_{A}. The magnitude of each current signal of the plurality of current signals corresponds to a value of the first digital operand 408. The current generation unit 404 comprises a current digital-to-analog converter configured to generate an output current signal representative of the first digital operand 408, and a current replication unit coupled to the current digital-to-analog converter. The current replication unit is configured to replicate the output current signal to generate the plurality of current signals I_{A}, as described with reference to FIG. 2. The plurality of current signals I_{A} are distributed to the plurality of switching units 406 via the plurality of output nodes of the current generation unit 404.

With continued reference to FIG. 4, the plurality of switching units 406 includes a first switching unit 406a, a second switching unit 406b, and a kth switching unit 406k. Each switching unit of the plurality of switching units 406 is respectively coupled to a respective output node of the plurality of output nodes of the current generation unit 404 to receive a respective current signal I_{A}. Each switching unit of the plurality of switching units 406 comprises a first switch and a second switch in series with the first switch. The first switch is configured to close based on a respective digit value of the set of digital values of the second digital operand 410 (OPs). The second switch is configured to close for a duration of a respective pulse signal of the plurality of pulse signals. The first switching unit 406a receives a digit value b₀, the second switching unit 406b receives a digit value b₁, and the kth switching unit 406k receives a digit value bₖ₋₁. The closing of each of the first switch and the second switch causes a respective current signal of the plurality of current signals to flow to the integrator unit 416 for the duration of the respective pulse signal. In this configuration, the first switch is configured to close based on the respective digit value of the set of digital values of the second digital operand 410 and each pulse signal of the plurality of pulse signals corresponds to a unit pulse signal. The at least one output signal comprises a plurality of output signals, and each output signal of the plurality of output signals represents a partial result of a multiplication operation between the first digital operand 408 and the second digital operand 410.

The memory unit 412 (MU) is coupled to the plurality of switching units 406 and is configured to store the set of digital values of the first digital operand 408 or the second digital operand 410. In the embodiment of FIG. 4, the memory unit 412 is coupled to the plurality of switching units 406 and is configured to store the set of digital values b₀, b₁, through bₖ₋₁ of the second digital operand 410. The memory unit 412 provides the respective digit values to control the first switches of the plurality of switching units 406. The digit values stored in the memory unit 412 control whether the first switches are closed (when the digit value is 1) or open (when the digit value is 0), enabling the operand values to be stored and reused across multiple operations.

As further shown in FIG. 4, the pulse generation unit 414 (PGU) is configured to generate unit pulse signals PSᵤ that are provided to the second switches of each switching unit of the plurality of switching units 406. Each pulse signal of the plurality of pulse signals corresponds to a unit pulse signal having a uniform duration. The unit pulse signals PSᵤ have a uniform duration corresponding to a unit pulse, rather than durations corresponding to different place values. In some embodiments, the pulse generation unit 414 may utilize an existing clock signal from RAM or other memory circuitry to generate the plurality of pulse signals, repurposing existing timing infrastructure. The unit pulse signals may be synchronized with clock signals used for memory refresh operations and other system timing, allowing the pulse timing to be coordinated with memory update. The use of unit pulse signals simplifies the pulse generation unit 414 to generate a single pulse width rather than multiple pulse widths corresponding to different place values.

The integrator unit 416 comprises a plurality of integrator circuits respectively coupled to outputs of the plurality of switching units 406. Each integrator circuit of the plurality of integrator circuits is configured to accumulate charge based on the flow of the respective current signal I_{A} via a respective switching unit of the plurality of switching units 406 when both the first switch and the second switch are closed. As an example, each integrator circuit of the plurality of integrator circuits comprises a capacitor coupled between an output node of the respective switching unit and a ground node. The integrator unit 416 receives a reset signal to reset each integrator circuit to an initial state prior to a multiplication operation. The multiplier circuit 402 further comprises a reset circuit coupled to each integrator circuit of the plurality of integrator circuits. The reset circuit is configured to reset each of the plurality of integrator circuits to an initial state prior to the multiplication operation. The integrator unit 416 generates a plurality of output voltages V₀, V₁, through Vₖ₋₁ corresponding to partial results of the multiplication operation, wherein each output voltage corresponds to the accumulated charge from a respective switching unit.

With continued reference to FIG. 4, the analog-to-digital conversion unit 418 comprises a plurality of analog-to-digital converters respectively coupled to the plurality of integrator circuits of the integrator unit 416. Each analog-to-digital converter of the plurality of analog-to-digital converters is configured to convert a respective output signal of the plurality of output signals to a respective digital value of a plurality of digital values. The analog-to-digital conversion unit 418 converts the plurality of output voltages V₀, V₁, through Vₖ₋₁ to a plurality of digital values Y₀, Y₁, through Yₖ₋₁. In the bit-spliced version of the architecture, more analog-to-digital converters are needed on the output side, with N analog-to-digital converters required for an N-bit number. However, this trade-off enables simplified pulse generation circuitry and single-cycle operation.

The digital reconstruction unit 420 is coupled to the plurality of analog-to-digital converters of the analog-to-digital conversion unit 418. The digital reconstruction unit 420 is configured to receive the plurality of digital values Y₀, Y₁, through Yₖ₋₁ from the plurality of analog-to-digital converters and combine the plurality of digital values through shifting operations to generate the digital output 422(Y) representing a result of the multiplication operation between the first digital operand 408 and the second digital operand 410. The shifting operations apply place values to the partial results digitally, where for binary representation with place values 2ⁱ, the digital reconstruction unit 420 shifts each partial result by the corresponding number of bit positions before accumulation. The digital reconstruction is straightforward because the place values are applied through shifting operations in the digital domain rather than through pulse durations in the analog domain. The digital reconstruction unit 420 implements the shifting operations using digital accumulators where results arriving in sequence are shifted and accumulated according to their bit positions, with multiple accumulators handling overflow. The place values are implicit and handled automatically by the digital reconstruction unit 420 to generate the final result of the multiplication operation between the first digital operand 408 and the second digital operand 410.

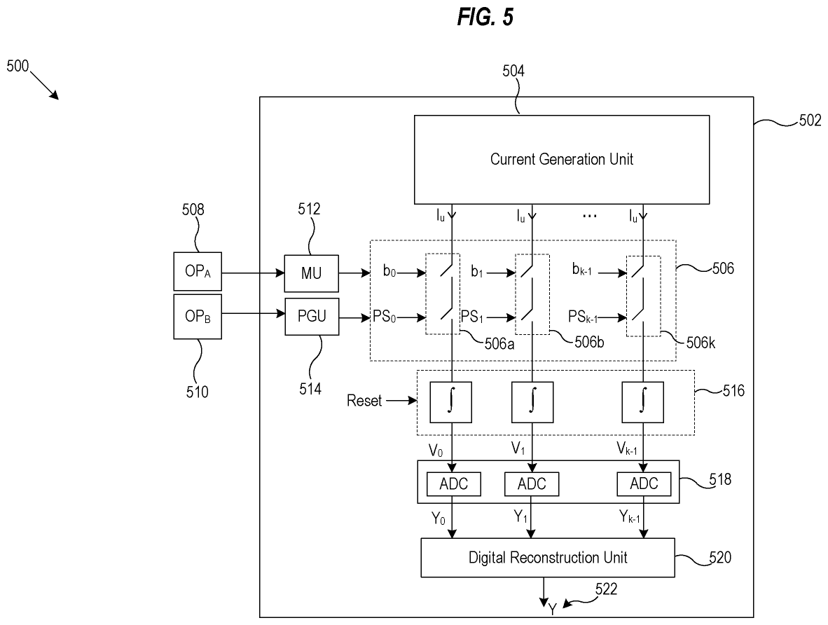

FIG. 5 is a diagram 500 illustrating a multiplier circuit 502 with unit current signals and pulse signals proportional to place values, in accordance with an embodiment of the disclosure. FIG. 5 is explained in conjunction with elements from FIG. 1, FIG. 2, FIG. 3, and FIG. 4. With reference to FIG. 5, the multiplier circuit 502 includes a current generation unit 504 configured to generate a plurality of current signals, a plurality of switching units 506 respectively coupled to a plurality of output nodes of the current generation unit 504, a memory unit 512 configured to store a set of digital values of a first digital operand 508 or a second digital operand 510, a pulse generation unit 514 configured to generate a plurality of pulse signals, an integrator unit 516 coupled to outputs of the plurality of switching units 506, an analog-to-digital conversion unit 518 comprising a plurality of analog-to-digital converters respectively coupled to the integrator unit 516, a digital reconstruction unit 520 coupled to the plurality of analog-to-digital converters, and a digital output 522. The multiplier circuit 502 is configured to perform multiplication operations between the first digital operand 508 and the second digital operand 510, wherein the integrator unit 516 is configured to generate at least one output signal based on the flow of a respective current signal of the plurality of current signals.

The current generation unit 504 is configured to receive the first digital operand 508 and generate the plurality of current signals. In the embodiment of FIG. 5, each current signal of the plurality of current signals is a unit current signal Iᵤ having a uniform magnitude. The current generation unit 504 provides the plurality of unit current signals Iᵤ to the plurality of switching units 506 via the plurality of output nodes of the current generation unit 504. The unit current signals Iₙ have uniform magnitudes rather than magnitudes proportional to the full value of the first digital operand 508 (as described in FIGS. 3-4). The unit current approach simplifies the current generation circuitry and enables bit-spliced processing where place values are applied digitally during reconstruction.

With continued reference to FIG. 5, the plurality of switching units 506 includes a first switching unit 506a, a second switching unit 506b, and a kth switching unit 506k. Each switching unit of the plurality of switching units 506 is respectively coupled to a respective output node of the plurality of output nodes of the current generation unit 504. Each switching unit of the plurality of switching units 506 comprises a first switch and a second switch in series with the first switch. The first switch is configured to close based on a respective digit value of the set of digital values of the first digital operand 508. The first switching unit 506a receives a digit value b₀, the second switching unit 506b receives a digit value b₁, and the kth switching unit 506k receives a digit value bₖ₋₁. The digit values b₀, b₁, and bₖ₋₁ represent the respective digit values of the set of digital values of the first digital operand 508. The second switch is configured to close for a duration of a respective pulse signal of the plurality of pulse signals. The closing of each of the first switch and the second switch causes a respective current signal of the plurality of current signals to flow to the integrator unit 516 for the duration of the respective pulse signal.

The memory unit 512 is coupled to the plurality of switching units 506 and is configured to store the set of digital values of the first digital operand 508 or the second digital operand 510. In the embodiment of FIG. 5, the memory unit 512 stores the set of digital values of the second digital operand 510 and provides the respective digit values b₀, b₁, and bₖ₋₁ to control the first switches of the first switching unit 506a, the second switching unit 506b, and the kth switching unit 506k, respectively. The digit values stored in the memory unit 512 control whether the first switches are closed (when the digit value is 1) or open (when the digit value is 0), enabling the operand values to be stored and reused across multiple operations.

As further shown in FIG. 5, the pulse generation unit 514 is configured to generate the plurality of pulse signals PS₀, PS₁, and PSₖ₋₁. Each pulse signal of the plurality of pulse signals has the duration that corresponds to a value of the second digital operand 510. The pulse generation unit 514 provides the plurality of pulse signals to the plurality of switching units 506, where each switching unit receives a respective pulse signal to control the second switch.

The integrator unit 516 is coupled to outputs of the plurality of switching units 506 and comprises a plurality of integrator circuits. Each integrator circuit of the plurality of integrator circuits is configured to accumulate charge based on the flow of the respective unit current signal Iᵤ via a respective switching unit of the plurality of switching units 506 when both the first switch and the second switch are closed. For example, each integrator circuit of the plurality of integrator circuits comprises a capacitor coupled between an output node of the respective switching unit and a ground node. The at least one output signal comprises a plurality of output signals, and each output signal of the plurality of output signals represents a partial result of a multiplication operation between the first digital operand 508 and the second digital operand 510. The integrator unit 516 receives a reset signal to reset each integrator circuit to an initial state prior to subsequent operations. The multiplier circuit 502 further comprises a reset circuit coupled to each integrator circuit of the plurality of integrator circuits. The reset circuit is configured to reset each of the plurality of integrator circuits to an initial state prior to the multiplication operation. The integrator unit 516 generates a plurality of output voltages V₀, V₁, and Bₖ₋₁ corresponding to the accumulated charge from each switching unit.

With continued reference to FIG. 5, the analog-to-digital conversion unit 518 comprises a plurality of analog-to-digital converters respectively coupled to the plurality of integrator circuits of the integrator unit 516. Each analog-to-digital converter of the plurality of analog-to-digital converters is configured to convert a respective output signal of the plurality of output signals to a respective digital value of a plurality of digital values Y₀, Y₁, and Yₖ₋₁.

The digital reconstruction unit 520 is coupled to the plurality of analog-to-digital converters of the analog-to-digital conversion unit 518 and is configured to receive the plurality of digital values from the plurality of analog-to-digital converters. The digital reconstruction unit 520 combines the plurality of digital values through shifting operations to generate a digital output representing a result of the multiplication operation between the first digital operand 508 and the second digital operand 510. The digital output 522(Y) represents the complete multiplication result. The digital reconstruction unit 520 applies the place values of the first digital operand 508 digitally, since the digit values of the first digital operand 508 control the first switches and unit current signals are generated by the current generation unit 504. The digital reconstruction unit 520 may perform place value application through left-shifting operations where results from different bit positions are shifted according to their respective place values before summation. For binary representation with place values 2ⁱ corresponding to the first digital operand 508, the digital reconstruction unit 520 shifts each partial result by the corresponding number of bit positions before accumulation, applying the place values of the first digital operand 508 digitally rather than through current magnitudes in the analog domain. This configuration where each current signal of the plurality of current signals is a unit current signal and the first switch is configured to close based on the respective digit value of the set of digital values of the first digital operand 508, combined with pulse signals having durations corresponding to the value of the second digital operand 510, provides a bit-spliced architecture that simplifies the current generation circuitry while enabling efficient multiplication through digital reconstruction of the place values associated with the first digital operand 508.

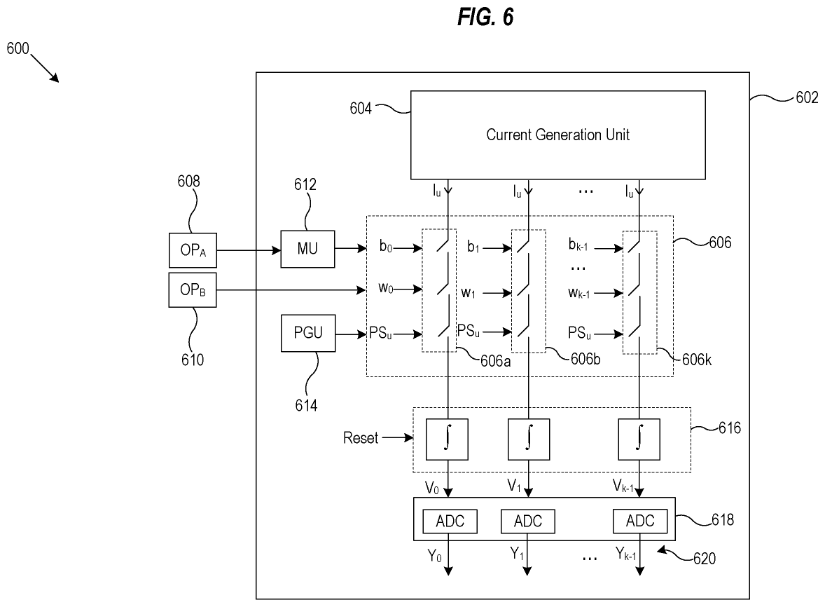

FIG. 6 is a diagram 600 illustrating a multiplier circuit 602 with unit current signals and unit pulse signals, in accordance with an embodiment of the disclosure. FIG. 6 is explained in conjunction with elements from FIGS. 1-5. With reference to FIG. 6, the multiplier circuit 602 includes a current generation unit 604 configured to generate a plurality of current signals, a plurality of switching units 606 respectively coupled to a plurality of output nodes of the current generation unit 604, a memory unit 612 configured to store a set of digital values of a first digital operand 608 or a second digital operand 610, a pulse generation unit 614 configured to generate a plurality of pulse signals, an integrator unit 616 coupled to outputs of the plurality of switching units 606, an analog-to-digital conversion unit 618 comprising a plurality of analog-to-digital converters respectively coupled to the integrator unit 616, a digital reconstruction unit 620 coupled to the plurality of analog-to-digital converters, and a digital output 622. The multiplier circuit 602 is configured to perform multiplication operations between the first digital operand 608 and the second digital operand 610, wherein the integrator unit 616 is configured to generate at least one output signal based on the flow of a respective current signal of the plurality of current signals.

The current generation unit 604 is configured to generate the plurality of current signals. In the embodiment of FIG. 6, each current signal of the plurality of current signals is a unit current signal Iᵤ having a uniform magnitude. The current generation unit 604 provides the plurality of unit current signals Iᵤ to the plurality of switching units 606 via the plurality of output nodes of the current generation unit 604. The unit current signals Iᵤ have uniform magnitudes rather than magnitudes proportional to the full value of the first digital operand 608, which simplifies the current generation circuitry and enables bit-spliced processing where place values are applied digitally during reconstruction.

With continued reference to FIG. 6, the plurality of switching units 606 includes a first switching unit 606a, a second switching unit 606b, and a kth switching unit 606k. Each switching unit of the plurality of switching units 606 is respectively coupled to a respective output node of the plurality of output nodes of the current generation unit 604. Each switching unit of the plurality of switching units 606 comprises a first switch, a second switch in series with the first switch, and a third switch in series with the first switch and the second switch. The first switch is configured to close based on a respective digit value of the set of digital values of the first digital operand 608. The first switching unit 606a receives a digit value b₀, the second switching unit 606b receives a digit value b₁, and the kth switching unit 606k receives a digit value bₖ₋₁. The digit values b₀, b₁, and bₖ₋₁ represent the respective digit values of the set of digital values of the first digital operand 608. The second switch is configured to close for a duration of a respective unit pulse signal PSᵤ of the plurality of pulse signals. The third switch is configured to close based on a respective digit value of the set of digital values of the second digital operand 610. The first switching unit 606a receives a digit value w₀ for the third switch, the second switching unit 606b receives a digit value w₁ for the third switch, and the kth switching unit 606k receives a digit value wₖ₋₁ for the third switch. The digit values w₀, w₁, and wₖ₋₁ represent the respective digit values of the set of digital values of the second digital operand 610. The closing of each of the first switch, the second switch, and the third switch causes a respective current signal of the plurality of current signals to flow to the integrator unit 616 for the duration of the respective pulse signal. This configuration of FIG. 6 represents a bit-spliced configuration where both current and time domains are bit-spliced with unit current sources and unit pulse signals, with both place values applied digitally during reconstruction.

The three-switch configuration enables the multiplier circuit 602 to process digit values from both the first digital operand 608 and the second digital operand 610 within each switching unit, where the first switch controls flow based on a digit value b₁ of the first digital operand 608, the third switch controls flow based on a digit value w₁ of the second digital operand 610, and the second switch controls the duration based on the unit pulse signal PSᵤ. The three switches in series implement the mathematical expression Yᵢ·Pᵤ·Xᵢ, where the first switch (digit value switch for the first operand) controls whether the bit of the first operand is on (1) or off (0), the third switch (digit value switch for the second operand) controls whether the bit of the second operand is on (1) or off (0), and the second switch (place value switch) controls the duration corresponding to the unit pulse. Both place values of the first digital operand 608 and the second digital operand 610 are applied digitally during reconstruction by the digital reconstruction unit 620.

The memory unit 612 is coupled to the plurality of switching units 606 and is configured to store the set of digital values of the first digital operand 608 or the second digital operand 610. In the embodiment of FIG. 6, the memory unit 612 stores the set of digital values of the first digital operand 608 and provides the respective digit values b₀, b₁, and bₖ₋₁ to control the first switches of the first switching unit 606a, the second switching unit 606b, and the kth switching unit 606k, respectively. The digit values stored in the memory unit 612 control whether the first switches are closed (when the digit value is 1) or open (when the digit value is 0), enabling the operand values to be stored and reused across multiple operations.

As further shown in FIG. 6, the pulse generation unit 614 is configured to generate the plurality of pulse signals. In the embodiment of FIG. 6, each pulse signal of the plurality of pulse signals is a unit pulse signal PSᵤ having a uniform duration. The pulse generation unit 614 provides the unit pulse signals PSᵤ to each of the plurality of switching units 606. The pulse generation unit 614 receives a clock signal for generating the unit pulse signals PSᵤ with precise timing. The unit pulse signals may be synchronized with clock signals used for memory refresh operations and other system timing, allowing the pulse timing to be coordinated with memory update. The use of unit pulse signals simplifies the pulse generation unit 614 to generate a single pulse width rather than multiple pulse widths corresponding to different place values. The use of unit pulse signals also improves the speed of operation compared to configurations where pulse durations are longer, such as configurations where pulse durations correspond to place values or to the full value of an operand. In configurations where pulse durations correspond to place values, the pulse widths may be 1, 2, 4, 8, and so on time units, requiring longer integration times for higher-order bit positions. In configurations where pulse durations correspond to the full value of an operand, the pulse width may be up to 2^{N-1} times a unit pulse duration for an N-bit operand, resulting in significantly longer operation times. By contrast, the unit pulse configuration enables faster operation because each pulse has a minimal uniform duration, with the place value information being applied digitally during reconstruction rather than through extended pulse durations in the analog domain. In some embodiments, the pulse generation unit 614 may utilize an existing clock signal from RAM or other memory circuitry to generate the plurality of pulse signals, repurposing existing timing infrastructure.

The integrator unit 616 is coupled to outputs of the plurality of switching units 606 and comprises a plurality of integrator circuits. Each integrator circuit of the plurality of integrator circuits is configured to accumulate charge based on the flow of the respective current signal via a respective switching unit of the plurality of switching units 606. When the first switch, the second switch, and the third switch are closed, the respective unit current signal Iᵤ flows to the respective integrator circuit. Each integrator circuit of the plurality of integrator circuits comprises a capacitor coupled between an output node of the respective switching unit and a ground node. The multiplier circuit 602 further comprises a reset circuit coupled to each integrator circuit of the plurality of integrator circuits. The reset circuit is configured to reset each of the plurality of integrator circuits to an initial state prior to the multiplication operation. The integrator unit 616 receives a reset signal for resetting the integrator circuits to the initial state prior to subsequent multiplication operations. The integrator unit 616 generates a plurality of output voltage signals V₀, V₁, through Vₖ₋₁ corresponding to the accumulated charge from each switching unit. The at least one output signal comprises a plurality of output signals, and each output signal of the plurality of output signals represents a partial result of a multiplication operation between the first digital operand 608 and the second digital operand 610.

With continued reference to FIG. 6, the analog-to-digital conversion unit 618 comprises a plurality of analog-to-digital converters respectively coupled to the plurality of integrator circuits of the integrator unit 616. Each analog-to-digital converter of the plurality of analog-to-digital converters is configured to convert a respective output signal of the plurality of output signals to a respective digital value of a plurality of digital values. The analog-to-digital conversion unit 618 outputs the plurality of digital values, denoted as Y₀, Y₁, through Yₖ₋₁, which represent partial results of the multiplication operation between the first digital operand 608 and the second digital operand 610.

The digital reconstruction unit 620 is coupled to the plurality of analog-to-digital converters of the analog-to-digital conversion unit 618 and is configured to receive the plurality of digital values from the plurality of analog-to-digital converters. The digital reconstruction unit 620 combines the plurality of digital values through shifting operations to generate the digital output 622 representing a result of the multiplication operation between the first digital operand 608 and the second digital operand 610. The digital reconstruction unit 620 implements the shifting operations using digital accumulators where results arriving in sequence are shifted and accumulated according to their bit positions, with multiple accumulators handling overflow. For binary representation with place values 2′, the digital reconstruction unit 620 shifts each partial result by the corresponding number of bit positions before accumulation, applying the place values of both the first digital operand 608 and the second digital operand 610 digitally rather than through current magnitudes or pulse durations in the analog domain. In some embodiments, the closing of each of the first switch, the second switch, and the third switch of each switching unit of the plurality of switching units 606 occurs within a single cycle such that the at least one output signal is generated in the single cycle. Single-cycle operation is achieved when the plurality of switching units 606 operate in parallel, with each switching unit processing a respective digit position simultaneously, enabling high throughput multiplication with reduced latency compared to sequential processing approaches.

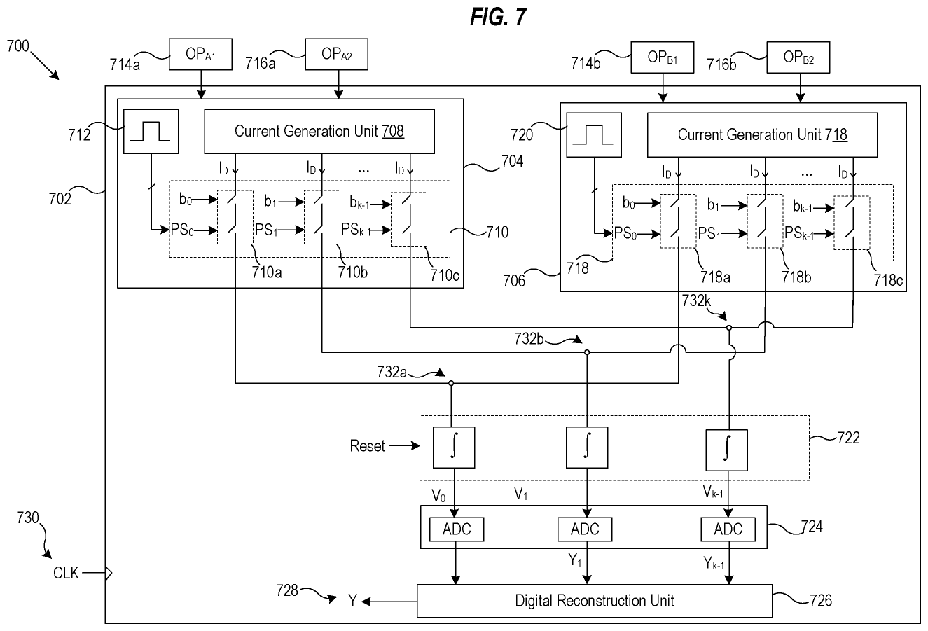

FIG. 7 is a diagram 700 illustrating a multiply-accumulate (MAC) circuit 702 with a plurality of multiplier circuits, in accordance with an embodiment of the disclosure. FIG. 7 is explained in conjunction with elements from FIGS. 1-6. With reference to FIG. 7, the MAC circuit 702 comprises a first multiplier circuit 704 and a second multiplier circuit 706. Each multiplier circuit of the plurality of multiplier circuits comprises a current generation unit configured to generate a plurality of current signals and a plurality of switching units respectively coupled to a plurality of output nodes of the current generation unit. The first multiplier circuit 704 comprises a first current generation unit 708 and a plurality of switching units 710 respectively coupled to a plurality of output nodes of the first current generation unit 708. The second multiplier circuit 706 comprises a current generation unit 718 and a plurality of switching units 718 respectively coupled to a plurality of output nodes of the current generation unit 718. Each multiplier circuit of the plurality of multiplier circuits may be configured according to any of the multiplier circuit embodiments described with reference to FIG. 1 through FIG. 6, including the multiplier circuit 102 of FIG. 1, the multiplier circuit 302 of FIG. 3, the multiplier circuit 402 of FIG. 4, the multiplier circuit 502 of FIG. 5, or the multiplier circuit 602 of FIG. 6. For example, each multiplier circuit may employ current signals having magnitudes corresponding to a value of a digital operand as described with reference to FIG. 3 and FIG. 4, or each multiplier circuit may employ unit current signals as described with reference to FIG. 5 and FIG. 6. The MAC circuit 702 is configured to perform multiply-accumulate operations on operand vectors, wherein the MAC circuit 702 computes a digital output 728 representing Y equal to OP_{A1} multiplied by OP_{A2} plus OP_{B1} multiplied by OP_{B2}. In alternative embodiments, the MAC circuit 702 may comprise more than two multiplier circuits to accommodate larger operand vectors, with each additional multiplier circuit contributing to the accumulated result.

With continued reference to FIG. 7, the plurality of switching units 710 of the first multiplier circuit 704 includes a first switching unit 710a, a second switching unit 710b, and a kth switching unit 710c. Each switching unit of the plurality of switching units 710 is respectively coupled to a respective output node of the plurality of output nodes of the first current generation unit 708. The plurality of switching units 718 of the second multiplier circuit 706 includes a first switching unit 718a, a second switching unit 718b, and a kth switching unit 718c. Each switching unit of the plurality of switching units 718 is respectively coupled to a respective output node of the plurality of output nodes of the current generation unit 718. Each switching unit of the plurality of switching units 710 and the plurality of switching units 718 comprises a first switch and a second switch in series with the first switch. The first switch is configured to close based on a respective digit value of a set of digital values of a respective first digital operand of a first operand vector or a respective second digital operand of a second operand vector. The second switch is configured to close for a duration of a respective pulse signal of a plurality of pulse signals. The closing of each of the first switch and the second switch causes a respective current signal of the plurality of current signals to flow to a respective shorted output node of a plurality of shorted output nodes 732a, 732b . . . 732k. The switching units receive respective digit values denoted as b₀, b₁, through bₖ₋₁ and respective pulse signals denoted as PS₀, PS₁, through PSₖ₋₁. Each switching unit receives a current signal I_{D} from the respective current generation unit. In some embodiments, each switching unit of the plurality of switching units 710 and the plurality of switching units 718 further comprises a third switch in series with the first switch and the second switch, where the third switch is configured to close based on a respective digit value of the set of digital values of the second digital operand of a respective operand vector, as described with reference to FIG. 6. The closing of each of the first switch, the second switch, and the third switch causes the respective current signal of the plurality of current signals to flow to the respective shorted output node.

The first current generation unit 708 receives a first digital operand 714a and a second digital operand 716a. The current generation unit 718 receives a first digital operand 714b and a second digital operand 716b. The first digital operand 714a and the first digital operand 714b form the first operand vector, and the second digital operand 716a and the second digital operand 716b form the second operand vector. The first current generation unit 708 is configured to generate the plurality of current signals based on the first digital operand 714a or the second digital operand 716a. The current generation unit 718 is configured to generate the plurality of current signals based on the first digital operand 714b or the second digital operand 716b. In certain embodiments, each current generation unit comprises a current digital-to-analog converter configured to generate an output current signal representative of the respective digital operand, and a current replication unit coupled to the current digital-to-analog converter. The current replication unit is configured to replicate the output current signal to generate the plurality of current signals, as described with reference to FIG. 2.

In some embodiments, a magnitude of each current signal of the plurality of current signals corresponds to a value of the respective digital operand, as described with reference to FIG. 3 and FIG. 4. In alternative embodiments, each current signal of the plurality of current signals is a unit current signal Iᵤ having a uniform magnitude, as described with reference to FIG. 5 and FIG. 6. The MAC circuit 702 may further comprise a memory unit coupled to the plurality of switching units 710 and the plurality of switching units 718, wherein the memory unit is configured to store the set of digital values of the first digital operand or the second digital operand, enabling the operand values to be stored and reused across multiple operations.

As further shown in FIG. 7, a first pulse generation unit 712 is configured to generate a first plurality of pulse signals for the first multiplier circuit 704, and a second pulse generation unit 720 is configured to generate a second plurality of pulse signals for the second multiplier circuit 706. The first pulse generation unit 712 is coupled to the first multiplier circuit 704 and provides the first plurality of pulse signals to the plurality of switching units 710. The second pulse generation unit 720 is coupled to the second multiplier circuit 706 and provides the second plurality of pulse signals to the plurality of switching units 718. The first pulse generation unit 712 and the second pulse generation unit 720 each receive a clock signal 730 for generating the respective plurality of pulse signals with precise timing. In some embodiments, the duration of each pulse signal of the plurality of pulse signals corresponds to a place value of a respective digit value of the set of digital values of the respective digital operand, as described with reference to FIG. 3 and FIG. 5. For example, the plurality of pulse signals may have durations of 1, 2, 4, 8, and so on pulse widths representing place values in binary representation, where the first pulse signal PS₀ has a duration of 1 time unit corresponding to the place value 2⁰, the second pulse signal PS₁ has a duration of 2 time units corresponding to the place value 2¹, and the kth pulse signal PSₖ₋₁ has a duration of 2^{k-1} time units corresponding to the place value 2^{k-1}. In alternative embodiments, each pulse signal of the plurality of pulse signals corresponds to a unit pulse signal PSᵤ having a uniform duration, as described with reference to FIG. 4 and FIG. 6, which simplifies the first pulse generation unit 712 and the second pulse generation unit 720 to generate a single pulse width rather than multiple pulse widths corresponding to different place values. The unit pulse signal may be synchronized with clock signals used for memory refresh operations and other system timing. The first pulse generation unit 712 and the second pulse generation unit 720 each comprise hardware that generates the plurality of pulse signals for the respective multiplier circuit, providing timing signals to the switching units of the respective multiplier circuit. As an example, each of the first pulse generation unit 712 and the second pulse generation unit 720 may be based on a digital-to-time converter circuit or a PWM circuit.

With continued reference to FIG. 7, the MAC circuit 702 comprises a plurality of shorted output nodes 732a, 732b . . . 732k. Each shorted output node of the plurality of shorted output nodes 732a, 732b . . . 732k is coupled to an output of a respective switching unit of each multiplier circuit of the plurality of multiplier circuits. The outputs of the plurality of switching units 710 and the plurality of switching units 718 are coupled to the plurality of shorted output nodes 732a, 732b . . . 732k. With each switching unit, the closing of each of the first switch and the second switch causes a respective current signal of the plurality of current signals to flow to a respective shorted output node of the plurality of shorted output nodes 732a, 732b . . . 732k. The MAC circuit 702 implements shorting of outputs from multiple switching units to a common wire where any number of multiplication blocks can be attached to the same wire for accumulation. For example, the output of the first switching unit 710a of the first multiplier circuit 704 and the output of the first switching unit 718a of the second multiplier circuit 706 are coupled to a first shorted output node 732a, the output of the second switching unit 710b of the first multiplier circuit 704 and the output of the second switching unit 718b of the second multiplier circuit 706 are coupled to a second shorted output node 732b, and the output of the kth switching unit 710c of the first multiplier circuit 704 and the output of the kth switching unit 718c of the second multiplier circuit 706 are coupled to a kth shorted output node 732k. The shorting of outputs does not result in loss of information for completing the multiplication before accumulation because the terms contain the multiplication of the digits and their respective locations, with place values handled implicitly by a digital reconstruction unit 726. The place values of the operands are implicit and handled automatically by the digital reconstruction unit 726.

An integrator unit 722 is coupled to the plurality of shorted output nodes 732a, 732b . . . 732k. The integrator unit 722 is configured to accumulate charge based on the flow of the respective current signal from the respective switching unit of each multiplier circuit of the plurality of multiplier circuits to generate at least one output signal. The integrator unit 722 comprises a plurality of integrator circuits that accumulate charge based on the flow of current signals from the switching units. Each integrator circuit of the plurality of integrator circuits comprises a capacitor coupled between an output node of the respective shorted output node and a ground node, as described with reference to FIG. 1 through FIG. 6. The integrator unit 722 receives a reset signal and generates a plurality of voltage signals V₀, V₁, through Vₖ₋₁. Each integrator circuit of the plurality of integrator circuits is configured to accumulate charge from the corresponding shorted output node, combining the current contributions from the first multiplier circuit 704 and the second multiplier circuit 706 at each bit position. The MAC circuit 702 further comprises a reset circuit coupled to each integrator circuit of the plurality of integrator circuits, where the reset circuit is configured to reset each of the plurality of integrator circuits to an initial state prior to the multiply-accumulate operation. In some embodiments, the closing of each of the first switch and the second switch of each switching unit of the plurality of switching units 710 and the plurality of switching units 718 occurs within a single cycle such that the at least one output signal is generated in the single cycle. Single-cycle operation is achieved when the plurality of switching units operate in parallel, with each switching unit processing a respective digit position simultaneously, enabling multiply-accumulate operations with reduced latency compared to sequential processing approaches.

An analog-to-digital conversion unit 724 is coupled to the integrator unit 722. The analog-to-digital conversion unit 724 comprises a plurality of analog-to-digital converters respectively coupled to the plurality of integrator circuits of the integrator unit 722. Each analog-to-digital converter of the plurality of analog-to-digital converters is configured to convert a respective output signal of the plurality of output signals to a respective digital value of a plurality of digital values Y₀, Y₁, through Yₖ₋₁. The digital reconstruction unit 726 is coupled to the analog-to-digital conversion unit 724 and receives the clock signal 730. The digital reconstruction unit 726 is configured to receive the plurality of digital values from the plurality of analog-to-digital converters and combine the plurality of digital values through shifting operations to generate the digital output 728 representing a result Y of the MAC operation. The digital reconstruction unit 726 implements the shifting operations using digital accumulators where results arriving in sequence are shifted and accumulated according to their bit positions, with multiple accumulators handling overflow, as described with reference to FIG. 1, FIG. 4, FIG. 5, and FIG. 6. For binary representation with place values 2′, the digital reconstruction unit 726 shifts each partial result by the corresponding number of bit positions before accumulation. The digital output 728 represents the computation Y equal to OP_{A1} multiplied by OP_{A2} plus OP_{B1} multiplied by OP_{B2}, where OP_{A1} and OP_{B1} represent the first operand vector and OP_{A2} and OP_{B2} represent the second operand vector.

In some embodiments, the MAC circuit 702 may be extended to perform matrix-vector multiplication where a row of input values is simultaneously applied across multiple columns of the plurality of multiplier circuits to produce a row of output results in a streaming fashion. In matrix-vector multiplication operations, a row of a matrix is simultaneously multiplied with multiple columns to produce a row of results. The streaming operation applies one row to the entire matrix to produce a row of results, and then applies the next row to produce another row of results. For example, when processing a matrix with dimensions M×N, the MAC circuit 702 may process M rows sequentially, where each row is applied to N columns simultaneously to produce N output values per row. This streaming approach enables efficient processing of matrix operations commonly used in machine learning applications, including neural network inference and digital signal processing. The MAC circuit 702 may include additional multiplier circuits beyond the first multiplier circuit 704 and the second multiplier circuit 706 to accommodate larger matrix dimensions, with each additional multiplier circuit comprising a current generation unit, a pulse generation unit, and a plurality of switching units coupled to the plurality of shorted output nodes. In some embodiments, the MAC circuit 702 may be configured in a differential version where complementary currents I and I-bar flow into respective locations with dependent switch control such that when one switch is on the complementary switch is off, providing improved noise rejection and signal integrity.

In some embodiments, the MAC circuit 702 may be configured such that both the first digital operand and the second digital operand are streaming inputs, with the output also streaming, such that no values are held or stored during operation. In this dual streaming configuration, both operands stream into the MAC circuit 702 and the digital output 728 streams out, providing unique system-level properties because no values are held or stored within the MAC circuit 702. This configuration differs from architectures where one operand resides in memory and the other operand streams in, as both operands flow through the MAC circuit 702 without being retained. The dual streaming configuration may enable continuous processing of operand sequences without the latency associated with loading operand values into memory storage. In alternative embodiments, the MAC circuit 702 may be configured such that the memory unit controls the time unit (the plurality of switching units 710 and the plurality of switching units 718) and the external input is applied to the current generation units, as described with reference to FIG. 3, FIG. 4, FIG. 5, and FIG. 6.

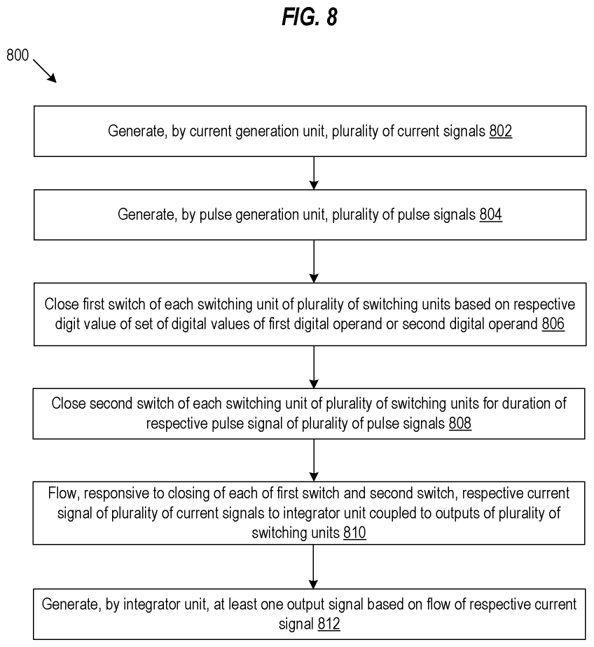

FIG. 8 is a flowchart depicting a method for performing a multiplication operation using a multiplier circuit, in accordance with an embodiment of the disclosure. FIG. 8 is explained in conjunction with elements from FIG. 1, FIG. 2, FIG. 3, FIG. 4, FIG. 5, FIG. 6, and FIG. 7. With reference to FIG. 8, there is shown a flowchart 800. The operations of the exemplary method may be executed by any of the multiplier circuits described herein, for example, by the multiplier circuit 102 of FIG. 1, the multiplier circuit 302 of FIG. 3, the multiplier circuit 402 of FIG. 4, the multiplier circuit 502 of FIG. 5, the multiplier circuit 602 of FIG. 6, or multiplier circuits in the MAC circuit 702 of FIG. 7. The operations of the flowchart 800 may start at 802.

At 802, the operations include generating, by a current generation unit, a plurality of current signals. The current generation unit may be configured as described with reference to FIG. 1 and FIG. 2, comprising a current digital-to-analog converter and a current replication unit. In some embodiments, a magnitude of each current signal corresponds to a value of the first digital operand. In alternative embodiments, each current signal is a unit current signal having a uniform magnitude. The operations proceed to 804.

At 804, the operations include generating, by a pulse generation unit, a plurality of pulse signals. The pulse generation unit may be configured as described with reference to FIG. 1 through FIG. 7. In some embodiments, a duration of each pulse signal corresponds to a place value of a respective digit value. In alternative embodiments, each pulse signal corresponds to a unit pulse signal having a uniform duration. The operations proceed to 806.

At 806, the operations include closing a first switch of each switching unit of a plurality of switching units based on a respective digit value of a set of digital values of a first digital operand or a second digital operand. Each switching unit comprises the first switch and a second switch in series with the first switch, as described with reference to FIG. 1 through FIG. 7. The first switch is configured to close when the respective digit value is 1 and remain open when the respective digit value is 0. The operations proceed to 808.

At 808, the operations include closing the second switch of each switching unit for a duration of a respective pulse signal of the plurality of pulse signals. The second switch is in series with the first switch within each switching unit. The closing of the second switch controls the time period during which current may flow through the switching unit when the first switch is also closed. The operations proceed to 810.

At 810, the operations include flowing, responsive to the closing of each of the first switch and the second switch, a respective current signal of the plurality of current signals to an integrator unit coupled to outputs of the plurality of switching units. The integrator unit receives the respective current signal when both the first switch and the second switch are closed, as described with reference to FIG. 1 through FIG. 7. In some embodiments, outputs of the plurality of switching units are shorted together at a common node coupled to the integrator unit. In alternative embodiments, the integrator unit comprises a plurality of integrator circuits configured to accumulate charge based on the flow of the respective current signal via a respective switching unit. The operations proceed to 812.

At 812, the operations include generating, by the integrator unit, at least one output signal based on the flow of the respective current signal. The integrator unit is configured to accumulate charge and generate the at least one output signal. In some embodiments, the at least one output signal comprises a plurality of output signals representing partial results of a multiplication operation. The at least one output signal may be provided to an analog-to-digital conversion unit and a digital reconstruction unit, as described with reference to FIG. 1, FIG. 4, FIG. 5, FIG. 6, and FIG. 7, to generate a digital output representing a result of the multiplication operation. In some embodiments, the closing of each of the first switch and the second switch of each switching unit occurs within a single cycle such that the at least one output signal is generated in the single cycle.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

What is claimed is:

1. A multiplier circuit, comprising:
a current generation unit configured to generate a plurality of current signals;
a plurality of switching units respectively coupled to a plurality of output nodes of the current generation unit;
a pulse generation unit configured to generate a plurality of pulse signals;
wherein:
each switching unit of the plurality of switching units comprises a first switch and a second switch in series with the first switch,
the first switch is configured to close based on a respective digit value of a set of digital values of a first digital operand or a second digital operand, and
the second switch is configured to close for a duration of a respective pulse signal of the plurality of pulse signals; and
an integrator unit coupled to outputs of the plurality of switching units, wherein:
the closing of each of the first switch and the second switch causes a respective current signal of the plurality of current signals to flow to the integrator unit for the duration,
the integrator unit is configured to generate at least one output signal based on the flow of the respective current signal.

2. The multiplier circuit of claim 1, wherein the current generation unit comprises:
a current digital-to-analog converter configured to generate an output current signal representative of the first digital operand; and
a current replication unit coupled to the digital-to-analog converter, wherein the current replication unit is configured to replicate the output current signal to generate the plurality of current signals.

3. The multiplier circuit of claim 2, wherein the current replication unit comprises:
a first transistor configured as a diode, wherein the first transistor is configured to receive the output current signal and generate a bias voltage; and
a parallel array of transistors coupled to the first transistor, wherein each transistor of the parallel array of transistors is configured to:
receive the bias voltage; and
mirror the output current signal to a respective output node of the plurality of output nodes.

4. The multiplier circuit of claim 1, wherein a magnitude of each current signal of the plurality of current signals corresponds to a value of the first digital operand.

5. The multiplier circuit of claim 4, wherein:
the first switch is configured to close based on the respective digit value of the set of digital values of the second digital operand,
the duration of each pulse signal of the plurality of pulse signals corresponds to a place value of respective digit value of the set of digital values of the second digital operand,
outputs of the plurality of switching units are shorted together at a common node coupled to the integrator unit, and
the at least one output signal represents a result of a multiplication operation between the first digital operand and the second digital operand.

6. The multiplier circuit of claim 4, wherein:
the first switch is configured to close based on the respective digit value of the set of digital values of the second digital operand,
each pulse signal of the plurality of pulse signals corresponds to a unit pulse signal,
the at least one output signal comprises a plurality of output signals, and
each output signal of the plurality of output signals represents a partial result of a multiplication operation between the first digital operand and the second digital operand.

7. The multiplier circuit of claim 1, wherein each current signal of the plurality of current signals is a unit current signal.

8. The multiplier circuit of claim 7, wherein the first switch is configured to close based on the respective digit value of the set of digital values of the first digital operand.

9. The multiplier circuit of claim 8, wherein each pulse signal of the plurality of pulse signals has the duration that corresponds to a value of the second digital operand.

10. The multiplier circuit of claim 8, wherein each pulse signal of the plurality of pulse signals is a unit pulse signal.

11. The multiplier circuit of claim 10, wherein each switching unit of the plurality of switching units further comprises a third switch in series with the first switch and the second switch, wherein the third switch is configured to close based on the respective digit value of the set of digital values of the second digital operand, and wherein the closing of each of the first switch, the second switch, and the third switch causes the respective current signal of the plurality of current signals to flow to the integrator unit.

12. The multiplier circuit of claim 1, wherein the at least one output signal comprises a plurality of output signals, and each output signal of the plurality of output signals represents a partial result of a multiplication operation between the first digital operand and the second digital operand.

13. The multiplier circuit of claim 12, wherein the integrator unit comprises a plurality of integrator circuits, and wherein each integrator circuit of the plurality of integrator circuits is configured to accumulate charge based on the flow of the respective current signal via a respective switching unit of the plurality of switching units.

14. The multiplier circuit of claim 13, wherein each integrator circuit of the plurality of integrator circuits comprises a capacitor coupled between an output node of the respective switching unit and a ground node.

15. The multiplier circuit of claim 13, further comprising:
an analog-to-digital conversion unit comprising a plurality of analog-to-digital converters respectively coupled to the plurality of integrator circuits, wherein each analog-to-digital converter of the plurality of analog-to-digital converters is configured to convert a respective output signal of the plurality of output signals to a respective digital value of a plurality of digital values; and
a digital reconstruction unit coupled to the plurality of analog-to-digital converters, wherein the digital reconstruction unit is configured to:
receive the plurality of digital values from the plurality of analog-to-digital converters; and
combine the plurality of digital values through shifting operations to generate a digital output representing a result of the multiplication operation between the first digital operand and the second digital operand.

16. The multiplier circuit of claim 13, further comprising a reset circuit coupled to each integrator circuit of the plurality of integrator circuits, wherein the reset circuit is configured to reset each of the plurality of integrator circuits to an initial state prior to the multiplication operation.

17. The multiplier circuit of claim 1, further comprising a memory unit is configured to store the set of digital values of the first digital operand or the second digital operand.

18. The multiplier circuit of claim 1, wherein the closing of each of the first switch and the second switch of each switching unit of the plurality of switching units occurs within a single cycle such that the at least one output signal is generated in the single cycle.

19. A multiply-accumulate (MAC) circuit, comprising:
a plurality of multiplier circuits, wherein each multiplier circuit of the plurality of multiplier circuits comprises:
a current generation unit configured to generate a plurality of current signals; and
a plurality of switching units respectively coupled to a plurality of output nodes of the current generation unit,
wherein each switching unit of the plurality of switching units comprises a first switch and a second switch in series with the first switch,
wherein:
the first switch is configured to close based on a respective digit value of a set of digital values of a respective first digital operand of a first operand vector or a respective second digital operand of a second operand vector, and
the second switch is configured to close for a duration of a respective pulse signal of a plurality of pulse signals;
a pulse generation unit configured to generate the plurality of pulse signals;
a plurality of shorted output nodes, wherein each shorted output node of the plurality of shorted output nodes is coupled to an output of a respective switching unit of each multiplier circuit of the plurality of multiplier circuits,
wherein the closing of each of the first switch and the second switch causes a respective current signal of the plurality of current signals to flow to a respective shorted output node of the plurality of shorted output nodes; and
an integrator unit coupled to the plurality of shorted output nodes, wherein the integrator unit is configured to accumulate charge based on the flow of the respective current signal from the respective switching unit of each multiplier circuit of the plurality of multiplier circuits to generate at least one output signal.

20. A method, comprising:
generating, by a current generation unit, a plurality of current signals;
generating, by a pulse generation unit, a plurality of pulse signals;
closing a first switch of each switching unit of a plurality of switching units based on a respective digit value of a set of digital values of a first digital operand or a second digital operand, wherein each switching unit of the plurality of switching units is coupled to a respective output node of a plurality of output nodes of the current generation unit, and wherein each switching unit of the plurality of switching units comprises the first switch and a second switch in series with the first switch;
closing the second switch of each switching unit of the plurality of switching units for a duration of a respective pulse signal of the plurality of pulse signals;
flowing, responsive to the closing of each of the first switch and the second switch, a respective current signal of the plurality of current signals to an integrator unit coupled to outputs of the plurality of switching units; and
generating, by the integrator unit, at least one output signal based on the flow of the respective current signal.
